(19) United States
(12) Patent Application Publication
(10) Pub. No.: US 2016/0333479 A1
(43) Pub. Date: Nov. 17, 2016

(54) APPARATUS AND METHOD FOR REGULATING THE TEMPERATURE IN A PROCESS CHAMBER OF A CVD REACTOR USING TWO TEMPERATURE SENSOR DEVICES

(71) Applicant: AIXTRON SE, Herzogenrath (DE)

(72) Inventors: Adam Boyd, Kelmis (BE); Peter Sebald Lauffer, Aachen (DE); Johannes Lindner, Roetogen (DE); Hugo Silva, Aachen (DE); Arne Theres, Stolberg (DE)

(21) Appl. No.: 15/105,515

(22) PCT Filed: Dec. 15, 2014
(86) PCT No.: PCT/EP2014/077788

§ 371 Date: Jul. 12, 2016

(30) Foreign Application Priority Data
Dec. 18, 2013 (DE) 10 2013 114 412.8

(51) Int. Cl. C23C 16/46

(52) U.S. Cl. CPC C23C 16/46

(57) ABSTRACT

An apparatus and a method for a thermal treatment, in particular a coating of a substrate, includes a heating device which is regulated by a regulating device which interacts with a first temperature sensor device. In order to counteract a temperature drift of the first temperature sensor device, a second temperature sensor device is used to detect the temperature drift and recalibrate the first temperature sensor device. The second temperature sensor device is used to measure the surface temperature of a substrate. This measured value is compared with a desired value, and if the desired value deviates from the measured actual value, a correction factor is formed and is used to apply the measured value used to regulate the heating device to the first temperature sensor device in order to bring the actual temperature value measured by the second temperature sensor device closer to the associated desired temperature value.

The invention relates to an apparatus for a thermal treatment, in particular a coating of at least one substrate, comprising a heating device which is regulated by a regulating device which cooperates with a first temperature sensor device, wherein the first temperature sensor device measures a first temperature on the upper side of a susceptor on which the at least one substrate rests during the treatment and comprising a second temperature sensor device which measures a second temperature on the upper side of the susceptor for correcting intervention in the regulating device in order to keep the surface temperature of the substrate at a desired value.

The invention further relates to a method for the thermal treatment of at least one substrate, in particular for the coating of the at least one substrate, wherein the at least one substrate rests on a susceptor which is heated from below to a treatment temperature by means of a heating device, wherein the heating device is regulated by a regulating device which cooperates with a first temperature sensor device, wherein a first temperature on the upper side of the susceptor is measured by means of the first temperature sensor device and a second temperature on the upper side of the susceptor is measured by means of a second temperature sensor device and a correcting intervention is made in the regulating device in order to keep the surface temperature of the substrate at a desired value.

A generic device and a generic method is described by U.S. Pat. No. 7,691,204 B2. Two different temperature sensor devices are used which measure the surface temperature of a substrate resting on the susceptor at two different locations. In this case, a plurality of pyrometers and an emissiometer are used. Different properties of the substrate heated to a treatment temperature are measured by the different temperature sensor devices in order to keep the surface temperature of the substrate at a constant value.

A method and a device for depositing layers on substrates is also previously known from DE 10 2012 101 717 A1.

A device according to the invention has a reactor housing and a process chamber disposed therein. The process chamber has a susceptor which can be heated from below by means of a heating device, for example, an infrared heater, an electrical resistance heater or an RF heater. At least one but preferably a plurality of substrates lie on a side of the susceptor facing the process chamber. The substrates comprise semiconductor wafers, for example, made of sapphire, silicon or a III-V material. Process gases are fed into the process chamber by means of a gas inlet unit, which process gases are pyrolytically decomposed there, wherein semiconductor layers, in particular III-V semiconductor layers, for example, InGaN or GaN layers are deposited on the substrate surfaces. Preferably quantum-well structures (QW), in particular multi-quantum well structures (NQW) made of InGaN/GaN are deposited in such devices. A regulating device which cooperates with a temperature sensor device is provided for regulating the temperature of the substrate surfaces which in particular must maintain a very precise value during deposition of the ternary layer. The temperature sensor device comprises a diode measuring array by means of which the temperature at various radial positions of the susceptor, which is rotatable about an axis of rotation, can be measured through gas outlet openings of the gas inlet unit.

In the prior art a two-colour pyrometer is used as temperature sensor device. This obtains a measured temperature value from an intensity measurement at two different wavelengths. In this case, the emissivity and an emissivity-corrected temperature is calculated. The pyrometer operates in the infrared range. Its advantage is the low sensitivity to rough surfaces.

It is further known to use infrared pyrometers which, for example, operate at a frequency of 950 nm. Pyrometers operating with IR however have the disadvantage that sapphire substrates are transparent to infrared light. Such pyrometers can thus only be used for measuring the temperature of the surface of the susceptor which consists of graphite.

The radiation emission of a sapphire substrate or the radiation emission of a layer deposited on a substrate, for example, a gallium nitride layer, can be measured by means of a UV pyrometer which operates at a wavelength of 405 nm. From a layer thickness of 1 to 2 μm, GaN layers become non-transparent for 405 nm. However, the absolute value of the radiation emission is considerably lower compared with the radiation emission in the infrared range at the treatment temperatures used so that a value obtained with a UV pyrometer is not suitable for regulating a heating device.

If only an IR two-colour pyrometer is used in a generic CVD reactor, only the surface temperature of the susceptor can be measured with this on account of the vertical temperature gradient inside the process chamber between the heated susceptor and the cooled gas outlet surface of the gas inlet unit, the substrate surface temperature is somewhat lower than the susceptor surface temperature.

In the prior art the surface temperature of the susceptor is measured through the gas outlet openings of the gas inlet unit having a diameter of about one to two millimetres. An unavoidable coating on the inner side of the gas outlet opening in the course of the treatment method leads to a variation of the effective optical cross-section or the optical transmission. As a result of the increasing coating of the gas outlet surface of the gas inlet unit and multiple reflections between susceptor and gas outlet surface, the contribution of the scattered light to the measurement result changes with time. Since a temperature which is not the target temperature is used for regulating the heating device, namely the temperature measured on the surface of the susceptor, i.e. light which is emitted by the susceptor itself is evaluated, a variation of the target temperature, namely the surface temperature of the substrate resting on the susceptor, cannot be avoided with the means used by the prior art.

It is the object of the invention to provide measures by means of which at least in intervals, the temperature difference of the actual temperature of the surface of the substrate from the desired treatment temperature is minimized.

The object is solved by the invention specified in the claims.

The subclaims not only describe advantageous further developments of the equivalent claims but also independent solutions of the object.

Initially and essentially it is proposed that the first temperature sensor device is adapted so that it measures substantially only the surface temperature of the upper side of the susceptor. The second temperature sensor device operates at a shorter wavelength than the first temperature sensor device and measures the surface temperature of the surface of the substrate or a layer which is deposited on the surface of the substrate. The treatment temperature, i.e. the surface temperature of the substrate, differs from this temperature by a temperature difference which varies in the course of the treatment process for the aforesaid reasons. This variation is determined by the second temperature sensor device. If the variation reaches a predefined threshold value, according to the invention a correcting intervention is made in the regulation. This can be accomplished for example by a modification of the desired temperature at which the regulating device keeps the surface temperature of the susceptor or by a correction factor.

The first temperature sensor device can comprise a plurality of individual sensors by means of which the surface temperature of a susceptor or a substrate resting on the susceptor can be determined. The second temperature sensor device is also able to determine the surface temperature of a susceptor or the surface temperature of a substrate resting on the susceptor. The temperature determination using the second temperature sensor device is made at a second location. The temperature determination using the first temperature sensor device is made at a first location. The two locations can be locally different. However, it is also possible that the two locations coincide locally. The two temperature sensor devices can be pyrometers. They can be formed by an infrared pyrometer and/or by a UV pyrometer. With the temperature sensor devices the reflectivity of the surface can be measured by the reflection of the light from a light source, for example, a laser or an LED, wherein the light of the light source has the same wavelength as that of the detector of the pyrometer (950 nm or 405 nm). This can be a two-colour pyrometer in which an intensity measurement is made at two different wavelengths and the emissivity and emissivity-corrected temperatures are calculated from the signal ratio of the intensities of the two wavelengths. This can be a UV pyrometer with a detection at 405 nm, i.e. a wavelength for which a GaN layer becomes non-transparent from a thickness of about 1 to 2 μm. In a particularly preferred embodiment of the invention, the two temperature sensor devices are formed by two different types of temperature sensor device. Thus, for example, one temperature sensor device, for example, the first temperature sensor device, can be an infrared pyrometer or a two-colour pyrometer. The second temperature sensor device can be a UV pyrometer. The apparatus according to the invention preferably has a gas inlet unit in the form of an actively cooled shower head. Such a gas inlet unit has a gas distribution chamber which is supplied with a process gas from outside. Preferred embodiments of the gas inlet unit have a plurality of separate gas distribution chambers, which are each supplied with a process gas from outside. The gas inlet unit has a gas outlet surface which has a plurality of gas outlet openings. The gas outlet openings can be formed by small tubes which are each connected to a gas distribution chamber. The first and/or second temperature sensor device can be located on the rear side of the gas distribution chamber. The first temperature sensor device preferably comprises an optical measuring device such as is described in DE 10 2012 101 717 A1. The sensor device has a plurality of sensor diodes which each lie at the end of an optical measuring section, wherein the optical measuring section passes through a gas outlet opening. The second temperature sensor device also sits on the rear side of a gas inlet unit and has a sensor element which sits at the end of an optical measuring section. Here also the optical measuring section goes through an opening of the gas inlet unit. This opening can comprise a gas outlet opening. However, it can also comprise an enlarged opening, for example, the opening of a through channel through the entire gas inlet unit. This opening can be flushed with an inert gas in order to avoid coatings being deposited on the inner walls of the opening. The preferred embodiment of the invention has a susceptor which is rotationally driven about a susceptor axis of rotation. The second temperature sensor device has a radial distance from the centre of rotation which is equal to the radial distance of at least one sensor element of the first temperature sensor device so that the temperature at one location on an identical circumferential circle around the centre of the susceptor can be measured with the first temperature sensor device and the second temperature sensor device. In a particularly preferred embodiment of the invention, the first temperature sensor device is formed by a diode array which measures a measured temperature value of the substrate or the susceptor surface at several locations. This is a IR two-colour pyrometer. In the particularly preferred embodiment of the invention, the second temperature sensor device is formed by a UV pyrometer which operates at 405 nm. InGaN multi-quantum wells can be deposited with the method according to the invention. In this case, thin InGaN layers are consecutively deposited multiple times on thin GaN layers. The substrate surface temperature or the susceptor surface temperature is preferably exclusively regulated using measured values which are supplied by the first temperature sensor device. As a result of the problems described initially, in particular a coating of the gas outlet surface or the gas outlet openings of the gas inlet unit through which the optical measuring section of the sensor elements runs, a falsification of the measurement results appears in the course of time, in particular after a multiplicity of coating steps. This has the result that the temperature to which the susceptor surface or the substrate surface is regulated no longer corresponds to the desired temperature. As a result of its arrangement and/or its mode of action, which can be different from the mode of action of the first temperature sensor device, the second temperature sensor device is not subjected to the temperature drift. This second temperature sensor device detects a varying surface temperature. If the second temperature sensor device is a UV pyrometer, for example, which measures the surface temperature of a substrate, the incorrect temperature which is attributable to the temperature drift is then detected at the latest when a sufficiently thick GaN layer has been deposited on the substrate, for example, the sapphire substrate. Whereas the first temperature sensor device measures the surface temperature of the susceptor, i.e. the temperature of a graphite surface, the second temperature sensor device measures the temperature of the surface of a substrate, in particular that is the temperature of a coating. As a result of the vertical temperature gradient in the process chamber, the temperature of the substrate surface is somewhat lower than the temperature of the susceptor surface. This systematic temperature difference is determined in preliminary experiments under ideal process conditions and taken into account in the subsequent recalibrating/correction. In a measurement time interval the surface temperature of the susceptor or the substrate is determined with the aid of the second temperature sensor device. Its deviation from a previously specified, desired temperature obtained for example in a coating step under ideal conditions is determined. Depending on the size of the deviation from the desired temperature, the regulating device or the first temperature sensor device is subjected to a correction value. As a result of such a recalibration, the regulating device is then able to regulate the substrate temperature or the susceptor temperature to the correct temperature value. It is further provided that in a deposition process which consists of a plurality of individual consecutive process sub-steps, the deviation of the actual temperature from the desired temperature is determined multiple times in one measurement interval. This is accomplished in each case by means of the second temperature sensor device. The corrective intervention in the regulation to compensate for the temperature drift can be restricted to a time interval, namely a correction interval. For example, the corrective intervention can only be made for those individual process steps in which the surface temperature of the substrate is particularly critical, for example, in process steps in which a ternary compound, for example InGaN is deposited. During deposition of a quantum-well sequence, for example, the GaN layer can be deposited without correcting intervention.

An exemplary embodiment of the invention is explained hereinafter with reference to appended drawings. In the figures:

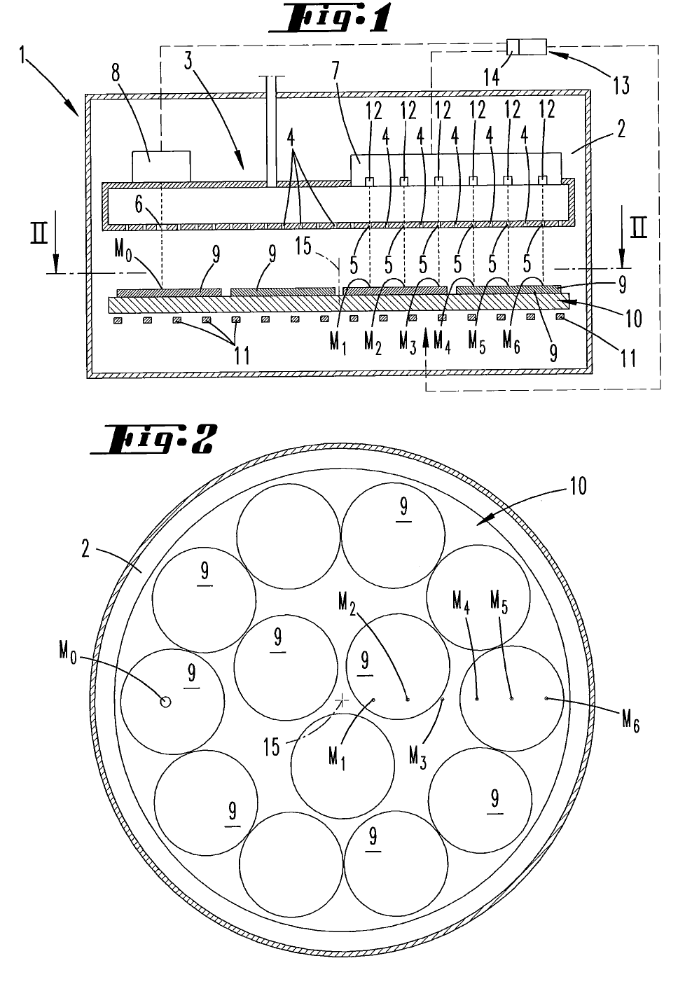

FIG. 1 shows a cross-section through a CVD reactor,

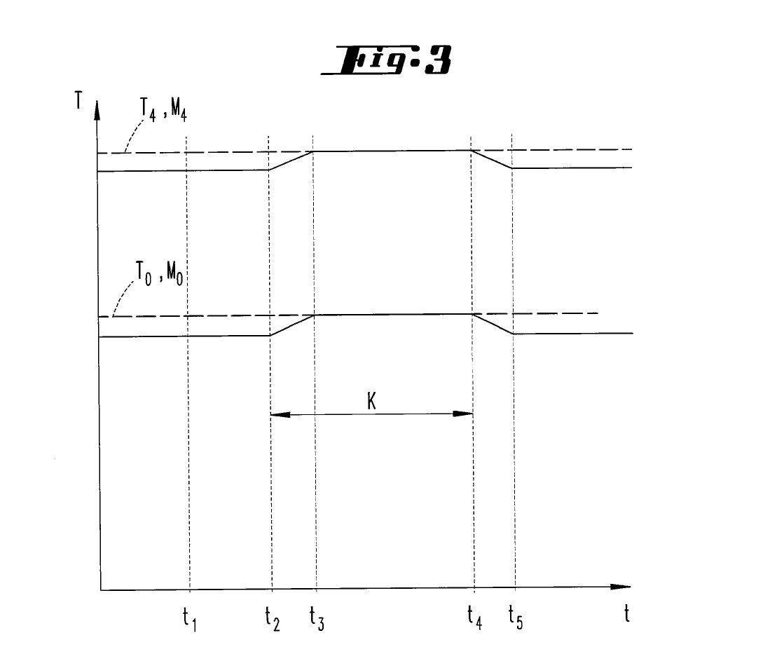

FIG. 2 shows a section along the line II-II with a view of the upper side of the susceptor,

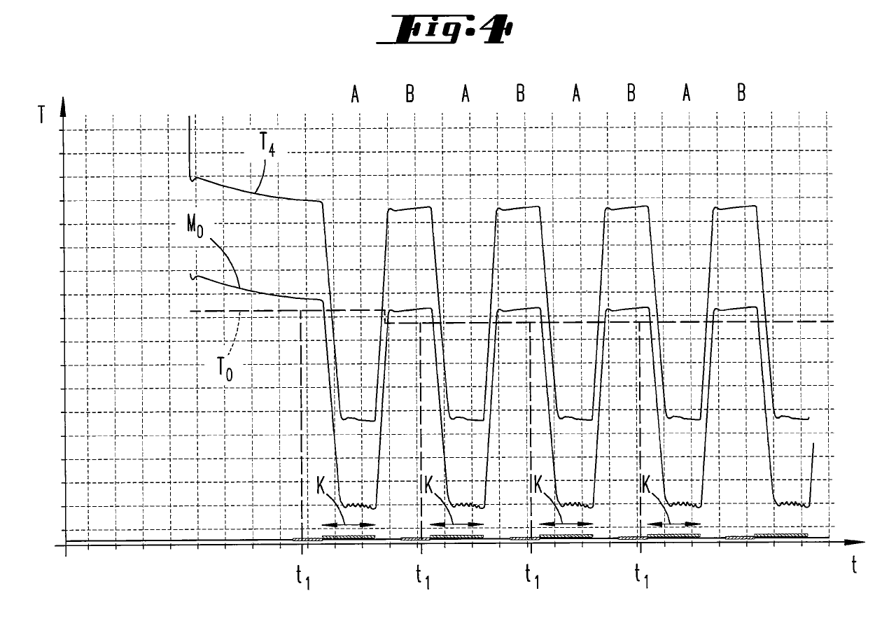

FIG. 3 shows a first time-temperature diagram to illustrate the method and

FIG. 4 shows a second time-temperature diagram to illustrate the method.

An apparatus according to the invention can have the structure shown in FIGS. 1 and 2. It consists of a CVD reactor 1 in the form of a gastight housing. Located inside the CVD reactor 1 is a gas inlet unit 3. The gas inlet unit comprises a flat, hollow circular-disk-shaped body in which a gas distribution chamber is located which is supplied with a process gas from outside. The process gas can flow out of gas outlet openings 4, 5, 6 from the gas distribution chamber into a process chamber 2. The gas outlet surface of the gas inlet unit which has the gas outlet openings 4, 5, 6 can be cooled.

The base of the process chamber 2 which lies opposite the gas outlet surface carries a plurality of substrates 9 to be coated. The susceptor forming the base can be rotated about an axis of rotation 15. Located underneath the susceptor is a heating device 11 in order to heat the susceptor.

The temperature of the susceptor upper side or the temperature of the substrates 9 lying on the susceptor upper side can be determined by means of a first temperature sensor device 7. For this purpose the first temperature sensor device 7 has a plurality of sensor diodes 12 which are disposed at different radial distance from the axis of rotation 15. Measurement points M₁, M₂, M₃, M₄, M₅ and M₆ on the upper side of the susceptor 10 pointing towards the process chamber 2 or the substrate 9 located thereon are located perpendicularly below a gas outlet opening 5 and a sensor diode 12 sitting on the rear wall of the gas inlet unit 3. It thus forms an optical path running parallel to the axis of rotation by means of which the surface temperature of the measurement points M₁ to M₆ can be measured by the first temperature sensor device 7 at different measurement locations. In each case, the measurement is made through a gas outlet opening 5.

The measured values supplied by the first temperature sensor device 7 are fed to a regulating device 13 which regulates the heating device 11 in such a manner that the surface temperature of the susceptor 10 or of the substrate 9 resting thereon is held at an actual value (range: 400° C. to 1200° C.)

A second temperature sensor device 8 is located on the side opposite the first temperature sensor device 7 in relation to the axis of rotation 15. Whereas the first temperature sensor device 7 is an infrared pyrometer, in particular a two-colour infrared pyrometer, the second temperature sensor device 8 comprises a temperature sensor of a different type. Here this comprises a UV pyrometer. Here also the measurement is made optically through an opening 6 of the gas inlet unit 3. In FIG. 1 the opening 6 is a larger-diameter gas outlet opening. In an exemplary embodiment not shown however, the sensor opening 6 is not connected to the gas distribution chamber so that no process gas flows into the process chamber 2 through the sensor opening 6. The surface temperature of a substrate 9 is measured using the second temperature sensor device 8 at the measurement location M₀. In the exemplary embodiment, the measurement location M₀ has the same radial distance from the axis of rotation 15 as the measurement location M₅. The measurement location M₅ and the measurement location M₀ thus lie on the same circumferential line.

The second temperature sensor device 8 delivers a temperature value at the measurement location M₀ which is compared by a comparator 14 with the temperature value delivered by the first temperature sensor device 7 for regulating the heating device 11. A calibration value is specified by means of a difference between these two temperatures, by means of which a calibration of the regulator 13 or of the first temperature sensor device 7 is made during a substrate coating process and/or between two substrate coating steps.

This calibration is explained in detail hereinafter with reference to FIG. 3. In a coating step (golden run) performed under ideal conditions, the measured temperature values which are to be measured at the measurement points M₁, M₂, M₃, M₄, M₅ and M₆ using the first temperature sensor device 7 under ideal conditions are determined. At the same time, the temperature correlating to this at the measurement location M₀ which is to be measured by means of the second temperature sensor device 8 under ideal conditions is determined. In general, the temperature measured at the measurement location M₀ will be somewhat lower than the temperature measured at the other measurement points M₁ to M₆.

In subsequent coating steps, the conditions deviate continuously from the ideal conditions so that the measured temperature value measured by the second sensor device 8 at the location M₀ no longer correlates with the value measured by the first temperature sensor device 7, for example, at the location M5 according to the ideal conditions.

FIG. 3 shows with the upper dashed line the course of a desired temperature T₄ which is measured at the measurement location M₄ on the susceptor under ideal conditions. The lower curve shows the temperature T₀ measured at the measurement location M₀ under ideal conditions on the substrate surface. After a plurality of coating steps, however the actual temperature T₄ measured at the measurement point M₄ is lower than the desired temperature. This is a consequence of the afore-mentioned temperature drift.

At the time t₁ the temperature deviation of the actual temperature is determined at the location M₀ (lower continuous line) in a measurement interval and compared with the desired temperature (lower dashed line). A calibration factor is determined from this temperature difference. This calibration factor is applied to the regulating device at time t₂. This has the result that the actual value of the susceptor (upper continuous line) increases to the desired value (upper dashed line). The interval in which the correction is made and which extends from the time t₂ to t₄ is designated by K. At the time t₃ the susceptor temperature has reached the desired value. The correlated desired temperature is measured at the measurement point M₀.

After performing a coating step, the correction interval is ended at time t₄. This has the result that the susceptor temperature (upper continuous line) decreases again in the time up to t₅.

FIG. 4 shows a similar view as FIG. 3 but a coating process which consists of two individual steps A, B which in the exemplary embodiment are repeated three times consecutively. In each case at a time t₁ a check is made in a measurement interval as to how far the temperature measured at the location M₀ differs from a desired value To. By reference to the size of the deviation, a correction factor is determined which is applied to the regulation during a correction interval K. In the respective phase A an InGaN layer is deposited for example at a lower temperature. In a following step in phase B a GaN layer is deposited at a higher temperature. However, a recalibration of the surface temperature of the substrate or the susceptor is only made here in the temperature-critical growth step in phase A.

The preceding explanations are used to explain the inventions covered overall by the application which in each case independently further develop the prior art at least by the following feature combinations, namely:

An apparatus characterized by a second temperature sensor device 8 for detecting a temperature drift of the first temperature sensor device 7, 12 and recalibrating the first temperature sensor device 7, 12.

A method characterized in that a temperature drift of the first temperature sensor device 7, 12 is detected using a second temperature sensor device 8 and the first temperature sensor device 7, 12 is recalibrated.

An apparatus or a method which are characterized in that the first temperature sensor device 7, 12 determines the temperature at a first location M₁, M₂, M₃, M₄, M₅, M₆ of a susceptor 10 or of a substrate 9 resting on the susceptor 10 and/or that the second temperature sensor device determines the temperature at a second location of the susceptor 10 or of a substrate 9 resting on the susceptor 10.

An apparatus or a method which are characterized in that the first and/or second temperature sensor device 7, 8 is an infrared pyrometer or a UV pyrometer.

An apparatus or a method which are characterized in that the two temperature sensor devices 7, 8 determine measured temperature values at different locations M₁, M₂, M₃, M₄, M₅, M₆, M₀ on the susceptor 10 or on a substrate 9 resting on the susceptor 10.

An apparatus or a method which are characterized in that the susceptor 9 can be rotated or is rotated about an axis of rotation and the two temperature sensor devices 7, 8 determine a surface temperature of the susceptor 10 or of a substrate 9 resting thereon at different circumferential positions but at the same radial distance from the axis of rotation.

An apparatus or a method characterized by a gas inlet unit which lies opposite a susceptor 10 and which has gas outlet openings 5, 6 pointing towards the susceptor 10 through which an optical sensor measuring section of the first temperature sensor device 7, 12 and/or of the second temperature sensor device 8 runs.

An apparatus or a method which are characterized in that the first temperature sensor device 7, 12 comprises a plurality of optical sensor elements 12 which determine measured temperature values of the surface of the susceptor pyrometrically in the infrared range at different radial distances from the axis of rotation 15 of the susceptor and that the second temperature sensor device 8 determines the surface temperature of a substrate 9 resting on the susceptor 10 at a different circumferential position pyrometrically in the UV range.

An apparatus or a method which are characterized in that in a measurement time interval t1 the surface temperature in particular of the substrate 9 is measured using the second temperature sensor device 8 and this measured value is compared with a desired value determined in preliminary experiments, wherein in the event of a deviation of the desired value from the measured actual value of the surface temperature, a correction factor is formed, which is applied to the measured value of the first temperature sensor device 7, 12 used to regulate the heating device 11 in order to bring the actual temperature value measured by the second temperature sensor device 8 closer to the relevant desired temperature value.

A method which is characterized in that in preliminary experiments under ideal conditions, the desired temperature of the desired temperature of the surface of the susceptor 10 measured by the first temperature sensor device 7, 12 is determined at which the surface temperature of the substrate 9 or of a layer deposited on the surface of the substrate 9 measured by the second temperature sensor device 8 corresponds to the desired treatment temperature wherein the desired value of the temperature of the substrate surface thus determined is used to regulate the heating device 11, that during the treatment or between consecutive process steps the actual temperature of the surface of the substrate 9 is measured in measurement intervals using the second temperature sensor device 8 and in the event of a deviation from the desired treatment temperature, a correcting intervention in the regulation is made.

A method which is characterized in that in the event of a deviation of the actual value measured by the second temperature sensor device 8 from the desired treatment temperature which exceeds a threshold value, a correction factor is applied to the measured value of the first temperature sensor device 7, 12 used to regulate the heating device 11 in order to bring the deviation of the actual temperature value measured by the second temperature sensor device 8 closer to the relevant desired temperature value.

All the disclosed feature (by themselves or in combination with one another) are essential to the invention. The disclosure content of the relevant/appended priority documents (copy of the prior application) is herewith also included in its full content in the disclosure of the application, also for the purpose of incorporating features of these documents in claims of the present application. The subclaims with their features characterize independent inventive further developments of the prior art, in particular in order to make divisional applications on the basis of these claims.

### REFERENCE LIST

1 CVD reactor
2 Process chamber
3 Gas inlet unit
4 Gas outlet opening
5 Sensor opening
6 Sensor opening
7 First temperature sensor device
8 Second temperature sensor device
9 Substrate
10 Susceptor
11 Heater
12 Sensor diode
13 Regulating device
14 Comparator
15 Axis of rotation
A Individual step
B Individual step
K Interval
M₀ Measurement location
M₁ Measurement location
M₂ Measurement location
M₃ Measurement location
M₄ Measurement location
M₅ Measurement location
M₆ Measurement location
Tₙ Temperature
tₙ Time

1. An apparatus for a thermal treatment of at least one substrate (9), in particular a coating of the at least one substrate (9), comprising a heating device (11) which is regulated by a regulating device (13) which cooperates with a first temperature sensor device (7, 12) in order to regulate measured values of the first temperature sensor device (7, 12) to a desired treatment temperature, wherein the first temperature sensor device (7, 12) measures a first temperature on an upper side of a susceptor (10) on which the at least one substrate (9) rests during the treatment and comprising a second temperature sensor device (8) which measures a second temperature on an upper side of the substrate (9), wherein the first temperature sensor device (7, 12) is adapted and disposed to measure a surface temperature of the upper side of the susceptor (10) and the second temperature sensor device (8) is sensitive at a shorter wavelength than the first temperature sensor device (7, 12) and is adapted and disposed to measure a surface temperature of the surface of the substrate (9) or of a layer deposited on the surface of the substrate (9),
wherein a deviation of the surface temperature of the substrate from the desired treatment temperature is determined using the second temperature sensor device (8) multiple times in each measurement interval during the thermal treatment,
wherein the surface temperature of the substrate deviates from the desired treatment temperature by a temperature difference which varies during the thermal treatment, and
wherein a correcting intervention is made to a temperature regulation of the regulating device (13) in order to bring the surface temperature of the substrate to the desired treatment temperature.

2. The apparatus according to claim 1, wherein the first temperature sensor device (7) is an infrared pyrometer and the second temperature sensor device (8) is a UV pyrometer.

3. The apparatus according to claim 1, wherein the two temperature sensor devices (7, 8) determine measured temperature values on the susceptor (10) or on a-the substrate (9) resting on the susceptor (10) at different locations (M₁, M₂, M₃, M₄, M₅, M₆, M₀).

4. The apparatus according to claim 1, wherein the susceptor (10) can be rotated or is rotated about an axis of rotation and the two temperature sensor devices (7, 8) determine a surface temperature of the susceptor (10) or the substrate (9) resting thereon at different circumferential positions but at the same radial distance from the axis of rotation.

5. The apparatus according to claim 1, further comprising an actively cooled gas inlet unit (3) which lies opposite the susceptor (10) and which has gas outlet openings (5, 6) pointing towards the susceptor (10), through which runs optical sensor measuring sections of the first temperature sensor device (7, 12) and/or of the second temperature sensor device (8).

6. The apparatus according to claim 1, wherein the first temperature sensor device (7, 12) comprises a plurality of optical sensor elements (12) which determine measured temperature values of the surface of the susceptor pyrometrically in the infrared range at different radial distances from an axis of rotation (15) of the susceptor, and wherein the second temperature sensor device (8) determines the surface temperature of the substrate (9) resting on the susceptor (10) at different circumferential positions from the axis of rotation pyrometrically in the UV range.

7. A method for a thermal treatment of at least one substrate (9), in particular for a coating of the at least one substrate (9), wherein the at least one substrate (9) rests on a susceptor (10) and is heated by means of a heating device (11), wherein the heating device (11) is regulated by a regulating device (13) which cooperates with a first temperature sensor device (7, 12) in order to regulate measured values of the first temperature sensor device (7, 12) to a desired treatment temperature, wherein a first temperature on an upper side of the susceptor (10) is measured by means of the first temperature sensor device (7, 12) and a second temperature on an upper side of the susceptor (10) is measured by means of a second temperature sensor device (8), wherein a surface temperature of the upper side of the susceptor (10) is measured with the first temperature sensor device (7, 12) and a surface temperature of the substrate (9) or of a layer deposited on the surface of the substrate (9) is measured with the second temperature sensor device (8) at a wavelength that is shorter than a wavelength measured by the first temperature sensor device (7, 12),
wherein a deviation of the surface temperature of the substrate from the desired treatment temperature is determined using the second temperature sensor device (8) multiple times in each measurement interval during the thermal treatment,
wherein the surface temperature of the substrate deviates from the desired treatment temperature by a temperature difference which varies during the thermal treatment, and
wherein a correcting intervention is made to a temperature regulation of the regulating device (13) in order to bring the surface temperature of the substrate to the desired treatment temperature.

8. The method according to claim 7, wherein the substrate (9) is transparent at a wavelength at which the first temperature sensor device (7, 12) is sensitive and is reflective at a wavelength at which the second temperature sensor device (8) is sensitive.

9. The method according to claim 7, wherein the first temperature sensor device (7, 12) is sensitive in the infrared range and the second temperature sensor device (8) is sensitive in the UV range.

10. The method according to claim 7, wherein the two temperature sensor devices (7, 8) determine measured temperature values on the susceptor (10) or on the substrate (9) resting on the susceptor (10) at different locations (M₁, M₂, M₃, M₄, M₅, M₆, M₀).

11. The method according to claim 7, wherein the susceptor (10) is rotated about an axis of rotation and the two temperature sensor devices (7, 8) determine a surface temperature of the susceptor (10) or of the substrate (9) resting thereon at different circumferential positions but at the same radial distance from the axis of rotation.

12. The method according to claim 7, wherein the first temperature sensor device (7, 12) comprises a plurality of optical sensor elements (12) which determine measured temperature values of the surface of the susceptor pyrometrically in the infrared range at different radial distances from an axis of rotation (15) of the susceptor and wherein the second temperature sensor device (8) determines the surface temperature of the substrate (9) resting on the susceptor (10) at different circumferential positions from the axis of rotation pyrometrically in the UV range.

13. The method according to claim 7, wherein in preliminary experiments under ideal conditions, the desired temperature of the surface of the susceptor (10) measured by the first temperature sensor device (7, 12) is determined at which the surface temperature of the substrate (9) or of a layer deposited on the surface of the substrate (9) measured by the second temperature sensor device (8) corresponds to the desired treatment temperature, wherein a desired value of the temperature of the substrate surface thus determined is used to regulate the heating device (11), wherein during the thermal treatment or between successive process steps in measuring intervals the temperature of the surface of the substrate (9) is measured using the second temperature sensor device (8) and if there is a deviation from the desired treatment temperature, a correcting intervention in the temperature regulation of the regulating device (13) is made.

14. The method according to claim 7, characterized in that if the temperature measured by the second temperature sensor device (8) deviates from the desired treatment temperature, at least one of the measured values of the first temperature sensor device (7, 12) used to regulate the heating device (11) is subjected to a correction factor or a desired value of the regulation of the heating device (11) is varied.

15. (canceled)
